(19) United States
(12) Patent Application Publication
(10) Pub. No.: US 2026/0150671 A1
(43) Pub. Date: May 28, 2026

(54) SEMICONDUCTOR PACKAGE STRUCTURE WITH HEAT DISSIPATION MECHANISM

(71) Applicant: Airoha Technology Corp., Hsinchu City (TW)

(72) Inventors: Ming-Tzong Yang, Hsinchu County (TW); Cheng-Hao Chang, Hsinchu County (TW); Chi-Fu Hsu, Hsinchu County (TW); Cheng-Chou Hung, Hsinchu County (TW)

(73) Assignee: Airoha Technology Corp., Hsinchu City (TW)

(21) Appl. No.: 19/074,460

(22) Filed: Mar. 10, 2025

Related U.S. Application Data
(60) Provisional application No. 63/724,417, filed on Nov. 25, 2024.

(51) Int. Cl. H01L 23/367; H01L 23/00; H01L 23/31; H01L 23/373

(52) U.S. Cl. CPC H10W 40/226; H10W 40/258; H10W 74/117; H10W 72/877; H10W 72/884; H10W 74/10; H10W 90/724; H10W 90/734; H10W 90/736; H10W 90/754

(57) ABSTRACT

A semiconductor package structure includes a functional die, a heat dissipation component, an adhesive, a molding compound, and a thermally conductive material. A bottom surface of the heat dissipation component is bonded to a top surface of the functional die via the adhesive. The functional die and the heat dissipation component are encapsulated by the molding compound. The thermally conductive material has a physical contact with a top surface of the heat dissipation component, wherein thermal conductivity of the heat dissipation component is higher than thermal conductivity of the modeling compound, and thermal conductivity of the thermally conductive material is higher than the thermal conductivity of the heat dissipation component.

### CROSS REFERENCE TO RELATED APPLICATIONS

This application claims the benefit of U.S. Provisional Application No. 63/724,417, filed on November 25th, 2024. The content of the application is incorporated herein by reference.

### BACKGROUND OF THE INVENTION

### 1. Field of the Invention

The present invention relates to a semiconductor package design, and more particularly, to a semiconductor package structure with a heat dissipation mechanism.

### 2. DESCRIPTION OF THE PRIOR ART

Recently, semiconductor dies capable of storing and processing huge amounts of data have been developed. As operation speeds have increased, a large amount of heat is generated from the semiconductor die. This heat generated from the semiconductor die may retard the operation speed of the semiconductor die, thus resulting in degraded performance of the semiconductor die. In general, one or more semiconductor dies may be packaged in the same semiconductor package. Thus, there is a need for an innovative semiconductor package structure which is capable of addressing a thermal issue caused by heat dissipated from semiconductor die(s).

### SUMMARY OF THE INVENTION

One of the objectives of the claimed invention is to provide a semiconductor package structure with a heat dissipation mechanism.

According to a first aspect of the present invention, an exemplary semiconductor package structure is disclosed. The exemplary semiconductor package structure includes a functional die, a heat dissipation component, an adhesive, a molding compound, and a thermally conductive material. A bottom surface of the heat dissipation component is bonded to a top surface of the functional die via the adhesive. The functional die and the heat dissipation component are encapsulated by the molding compound. The thermally conductive material has a physical contact with a top surface of the heat dissipation component, wherein thermal conductivity of the heat dissipation component is higher than thermal conductivity of the modeling compound, and thermal conductivity of the thermally conductive material is higher than the thermal conductivity of the heat dissipation component.

According to a second aspect of the present invention, an exemplary semiconductor package structure is disclosed. The exemplary semiconductor package structure has a functional die, a heat dissipation component, and an adhesive. A bottom surface of the heat dissipation component is bonded to a top surface of the functional die via the adhesive. The semiconductor package structure is a flip chip (FC) based semiconductor package structure. A size of the heat dissipation component is larger than a size of the functional die, and the heat dissipation component completely covers the functional die.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a section view of a first wire bond based semiconductor package structure according to an embodiment of the present invention.

FIG. 2 is a section view of a second wire bond based semiconductor package structure according to an embodiment of the present invention.

FIG. 3 is a section view of a first flip chip based semiconductor package structure according to an embodiment of the present invention.

FIG. 4 is a section view of a second flip chip based semiconductor package structure according to an embodiment of the present invention.

FIG. 5 is a section view of a third flip chip based semiconductor package structure according to an embodiment of the present invention.

FIG. 6 is a section view of a fourth flip chip based semiconductor package structure according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

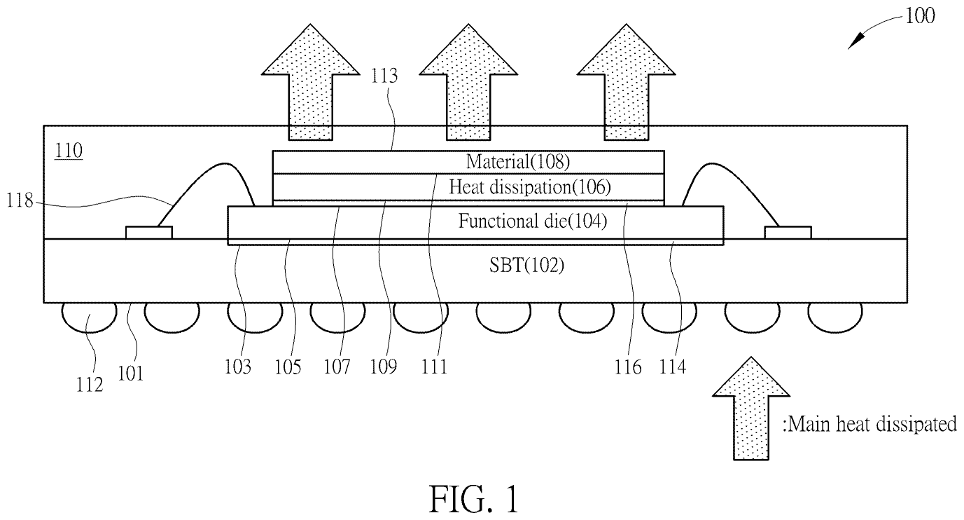

FIG. 1 is a section view of a first wire bond (WB) based semiconductor package structure according to an embodiment of the present invention. The WB based semiconductor package structure 100 includes a substrate (labeled by “SBT”) 102, a functional die (which includes active circuits such as transistor-based circuits) 104, a heat dissipation component (labeled by “heat dissipation”) 106, a thermally conductive material (labeled by “material”) 108, a molding compound 110, a plurality of solder balls 112, a plurality of adhesives 114, 116, and a plurality of bond wires 118. The solder balls 112 are formed on a bottom surface 101 of the substrate 102, and are used for printed circuit board (PCB) mounting. The adhesives 114 and 106 may be epoxy adhesive films. A bottom surface 105 of the functional die 104 is bonded to a top surface 103 of the substrate 102 via the adhesive 114. A bottom surface 109 of the heat dissipation component 106 is bonded to a top surface 107 of the functional die 104 via the adhesive 116.

The functional die 104 and the heat dissipation component 106 are encapsulated by the molding compound 110. In this embodiment, the heat dissipation component 106 provides heat dissipation pathways for the functional die 104 beneath the heat dissipation component 106. Hence, the thermal conductivity of the heat dissipation component 106 is higher than the thermal conductivity of the modeling compound 110. For example, the thermal conductivity of the modeling compound 110 is 1 Watts per meter-Kelvin (W/mk), and the thermal conductivity of the heat dissipation component 106 is not lower than 141 W/mk. In this embodiment, the heat dissipation component 106 is plated with the thermally conductive material 108, where the thermal conductivity of the thermally conductive material 108 is higher than that of the heat dissipation component 106. For example, the heat dissipation component 106 may be a dummy silicon die, where the material of the dummy silicon die is silicon (Si) with thermal conductivity of 141 W/mk, and the dummy silicon die has no active circuits such as transistor-based circuits. Since the thermally conductive material 108 has a physical contact with a top surface 111 of the heat dissipation component 106 and the thermal conductivity of the thermally conductive material 108 is higher than that of the heat dissipation component 106, the thermally conductive material 108 can improve the heat dissipation performance of the WB based semiconductor package structure 100. For example, the thermal conductivity of the thermally conductive material 108 may be higher than 141 W/mk.

In some embodiments of the present invention, the thermally conductive material 108 may be electrically conductive. For example, the thermally conductive material 108 may be silver (Ag) with thermal conductivity of 429 W/mk, copper (Cu) with thermal conductivity of 401 W/mk, gold (Au) with thermal conductivity of 317 W/mk, or aluminum (Al) with thermal conductivity of 237 W/mk. Hence, the heat dissipation component 106 may be electrically non-conductive to protect the functional die 104 from being unexpectedly shorted due to the thermally conductive material 108 that is electrically conductive (that is, the heat dissipation component 106 includes an electrically insulating material, and the thermally conductive material 108 includes an electrically conductive material). For example, the heat dissipation component 106 may be a dummy silicon die, where the material of the dummy silicon die is silicon (Si) with thermal conductivity of 141 W/mk, and the dummy silicon die has no active circuits such as transistor-based circuits.

Regarding the WB based semiconductor package structure 100 shown in FIG. 1, the thermally conductive material 108 is encapsulated by the molding compound 110, without being exposed to an external environment from the molding compound 110. Specifically, a top surface 113 of the thermally conductive material 108 is fully covered by the molding compound 110 and each side wall of the thermally conductive material 108, as seen in each cross-sectional view, is fully covered by the molding compound 110, although only one cross-sectional view is illustrated in FIG. 1, and all of functional die 104, heat dissipation component (e.g., dummy silicon die) 106, and thermally conductive material 108 are sealed by the molding compound 110.

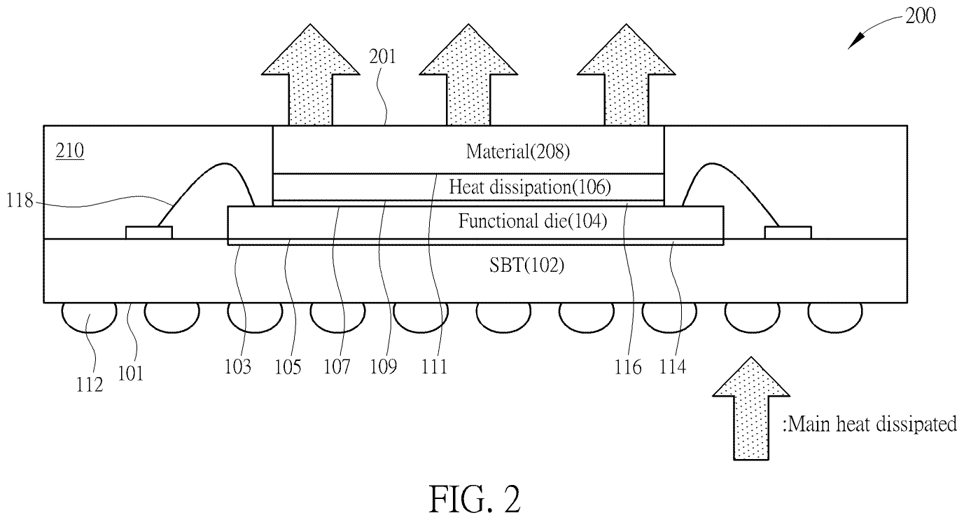

FIG. 2 is a section view of a second WB based semiconductor package structure according to an embodiment of the present invention. The major difference between the WB based semiconductor package structures 100 and 200 is that the thermally conductive material 208 (e.g., Ag, Cu, Au, Al, or other material with thermal conductivity higher than that of Si) is partially encapsulated by the molding compound 210, and is exposed to an external environment from the molding compound 210. The heat dissipation component (e.g., dummy silicon die) 106 is plated with the thermally conductive material 208. The functional die 104 and the heat dissipation component (e.g., dummy silicon die) 106 are encapsulated by the molding compound 210. A top surface 201 of the thermally conductive material 208 is not covered by the molding compound 210. Since the thermally conductive material 208 is exposed to the external environment, the WB based semiconductor package structure 200 has better heat dissipation performance than the WB based semiconductor package structure 100.

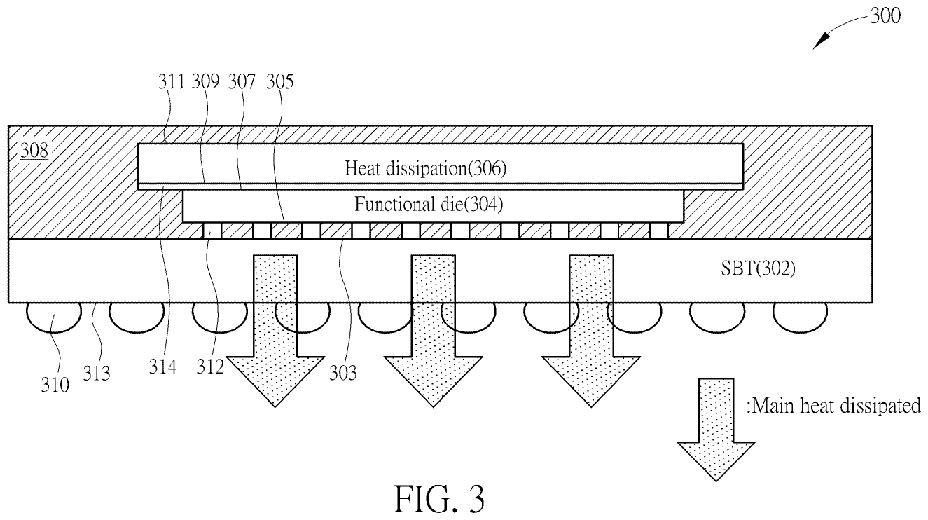

FIG. 3 is a section view of a first flip chip (FC) based semiconductor package structure according to an embodiment of the present invention. The FC based semiconductor package structure 300 includes a substrate (labeled by “SBT”) 302, a functional die (which includes active circuits such as transistor-based circuits) 304, a heat dissipation component (labeled by “heat dissipation”) 306, a molding compound 308, a plurality of solder balls 310, a plurality of bumps 312, and an adhesive 314. The solder balls 310 are formed on a bottom surface 313 of the substrate 302, and are used for PCB mounting. The bumps 312 are formed on a bottom surface 305 (i.e., active surface) of the functional die 304, and are used for substrate mounting. The adhesive 314 may be an epoxy adhesive film. A bottom surface 309 of the heat dissipation component 306 is bonded to a top surface 307 of the functional die 304 via the adhesive 314.

The functional die 304 and the heat dissipation component 306 are encapsulated by the molding compound 308. In this embodiment, the heat dissipation component 306 provides heat dissipation pathways for the functional die 304 beneath the heat dissipation component 306. Hence, the thermal conductivity of the heat dissipation component 306 is higher than that of the modeling compound 308. For example, the thermal conductivity of the modeling compound 308 is 1 W/mk, and the thermal conductivity of the heat dissipation component 306 is not lower than 141 W/mk. For example, the heat dissipation component 306 may be a dummy silicon die, where the material of the dummy silicon die is silicon (Si) with thermal conductivity of 141 W/mk, and the dummy silicon die has no active circuits such as transistor-based circuits.

In this embodiment, a size of the heat dissipation component (e.g., dummy silicon die) 306 is larger than a size of the functional die 304, and the heat dissipation component (e.g., dummy silicon die) 306 completely covers the functional die 304. Specifically, in a thickness direction (i.e., vertical direction) of the FC based semiconductor package structure 300, a surface area of the heat dissipation component (e.g., dummy silicon die) 306, substantially orthogonal to the thickness direction, is larger than a surface area of the functional die 304, and the surface area of the functional die 304 fully overlaps the surface area of the heat dissipation component (e.g., dummy silicon die) 306. That is, in the cross-sectional view of FIG. 3, as well as in other different cross-sectional views, the surface area of the functional die 304 fully overlaps the surface area of the heat dissipation component (e.g., dummy silicon die) 306. Since the heat dissipation component (e.g., dummy silicon die) 306 has large size and high thermal conductivity, it can improve the heat dissipation performance of the FC based semiconductor package structure 300.

Regarding the FC based semiconductor package structure 300 shown in FIG. 3, the heat dissipation component (e.g., dummy silicon die) 306 is encapsulated by the molding compound 308, without being exposed to an external environment from the molding compound 308. Specifically, a top surface 311 of the heat dissipation component (e.g., dummy silicon die) 306 is fully covered by the molding compound 308, and both of functional die 304 and heat dissipation component (e.g., dummy silicon die) 306 are sealed by the molding compound 308.

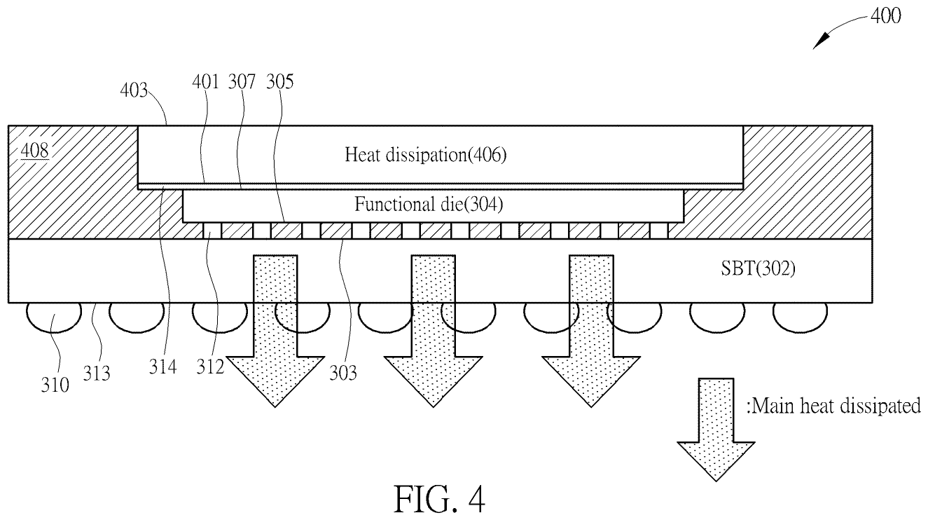

FIG. 4 is a section view of a second FC based semiconductor package structure according to an embodiment of the present invention. The major difference between the FC based semiconductor package structures 300 and 400 is that the heat dissipation component (e.g., dummy silicon die) 406 is partially encapsulated by the molding compound 408, and is exposed to an external environment from the molding compound 408. As shown in FIG. 4, a bottom surface 401 of the heat dissipation component (e.g., dummy silicon die) 406 is bonded to the top surface 307 of the functional die 304 via the adhesive 314, where a size of the heat dissipation component (e.g., dummy silicon die) 406 is larger than a size of the functional die 304, and the heat dissipation component (e.g., dummy silicon die) 406 completely covers the functional die 304. That is, in a thickness direction (i.e., vertical direction) of the FC based semiconductor package structure 400, a surface area of the heat dissipation component (e.g., dummy silicon die) 406, substantially orthogonal to the thickness direction, is larger than a surface area of the functional die 304, and the surface area of the functional die 304 fully overlaps the surface area of the heat dissipation component (e.g., dummy silicon die) 406. That is, in the cross-sectional view of FIG. 4, as well as in other different cross-sectional views, the surface area of the functional die 304 fully overlaps the surface area of the heat dissipation component (e.g., dummy silicon die) 406. In this embodiment, the functional die 304 is encapsulated by the molding compound 408; and a top surface 403 of the heat dissipation component (e.g., dummy silicon die) 406 is not covered by the molding compound 408. Since the heat dissipation component (e.g., dummy silicon die) 406 is exposed to the external environment from the molding compound 408, the FC based semiconductor package structure 400 has better heat dissipation performance than the FC based semiconductor package structure 300.

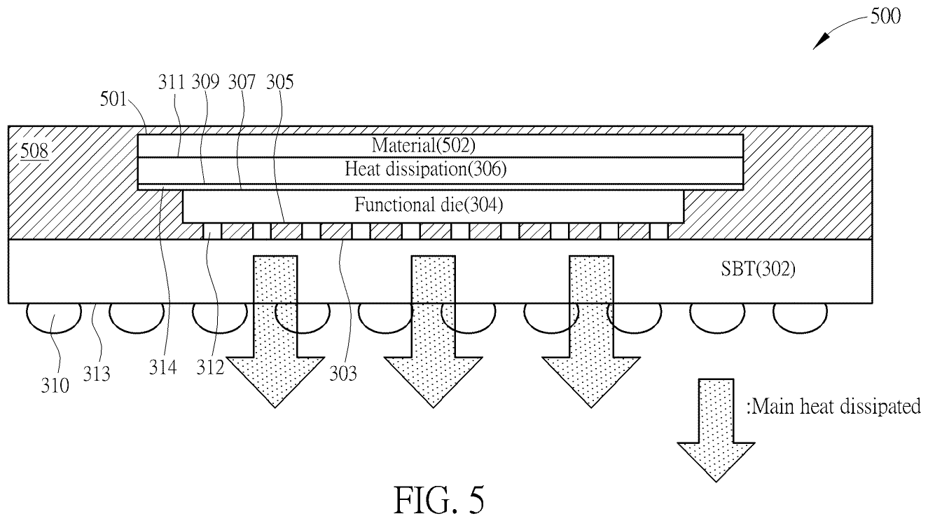

FIG. 5 is a section view of a third FC based semiconductor package structure according to an embodiment of the present invention. The major difference between the FC based semiconductor package structures 300 and 500 is that the heat dissipation component 306 is plated with a thermally conductive material (labeled by “material”) 502. The functional die 304 and the heat dissipation component 306 are encapsulated by the molding compound 508. In this embodiment, the heat dissipation component 306 provides heat dissipation pathways for the functional die 304 beneath the heat dissipation component 306. Hence, the thermal conductivity of the heat dissipation component 306 is higher than that of the modeling compound 508. For example, the thermal conductivity of the modeling compound 508 is 1 W/mk, and the thermal conductivity of the heat dissipation component 306 is not lower than 141 W/mk. In addition, the thermal conductivity of the thermally conductive material 502 is higher than the thermal conductivity of the heat dissipation component 306. For example, the heat dissipation component 306 may be a dummy silicon die, where the material of the dummy silicon die is silicon (Si) with thermal conductivity of 141 W/mk, and the dummy silicon die has no active circuits such as transistor-based circuits. Since the thermally conductive material 502 has a physical contact with a top surface 311 of the heat dissipation component 306 and the thermal conductivity of the thermally conductive material 502 is higher than the thermal conductivity of the heat dissipation component 306, the thermally conductive material 502 can improve the heat dissipation performance of the FC based semiconductor package structure 500. For example, the thermal conductivity of the thermally conductive material 502 is higher than 141 W/mk.

In some embodiments of the present invention, the thermally conductive material 502 may be electrically conductive. For example, the thermally conductive material 502 may be silver (Ag) with thermal conductivity of 429 W/mk, copper (Cu) with thermal conductivity of 401 W/mk, gold (Au) with thermal conductivity of 317 W/mk, or aluminum (Al) with thermal conductivity of 237 W/mk. Hence, the heat dissipation component 306 may be electrically non-conductive to protect the functional die 304 from being unexpectedly shorted due to the thermally conductive material 502 that is electrically conductive (that is, the heat dissipation component 106 includes an electrically insulating material, and the thermally conductive material 108 includes an electrically conductive material). For example, the heat dissipation component 306 may be a dummy silicon die, where the material of the dummy silicon die is silicon (Si) with thermal conductivity of 141 W/mk, and the dummy silicon die has no active circuits such as transistor-based circuits.

Regarding the FC based semiconductor package structure 500 shown in FIG. 5, the thermally conductive material 502 is encapsulated by the molding compound 508, without being exposed to an external environment from the molding compound 508. Specifically, a top surface 501 of the thermally conductive material 502 is fully covered by the molding compound 508 and each side wall of the thermally conductive material 502, as seen in each cross-sectional view, is fully covered by the molding compound 508, although only one cross-sectional view is illustrated in FIG. 5, and all of functional die 304, heat dissipation component (e.g., dummy silicon die) 306, and thermally conductive material 502 are sealed by the molding compound 508.

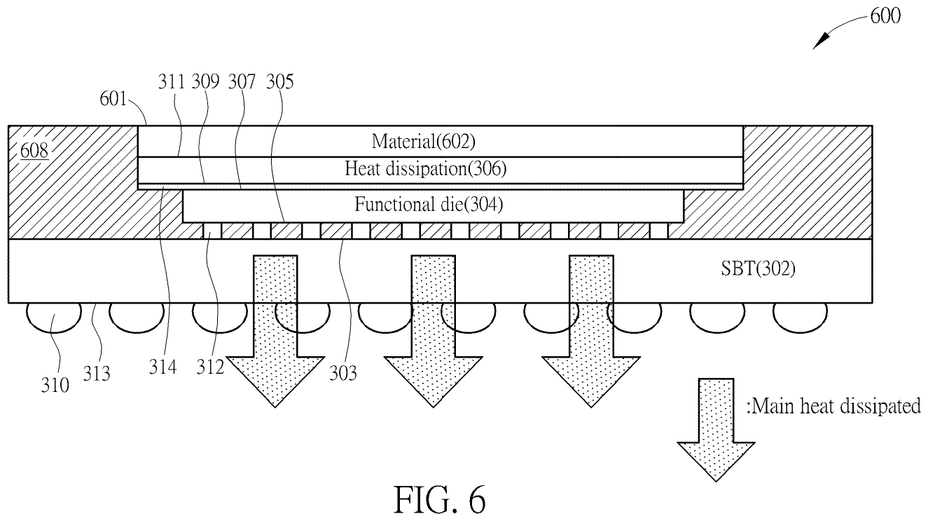

FIG. 6 is a section view of a fourth FC based semiconductor package structure according to an embodiment of the present invention. The major difference between the FC based semiconductor package structures 500 and 600 is that the thermally conductive material 602 (e.g., Ag, Cu, Au, Al, or other material with thermal conductivity higher than that of Si) is partially encapsulated by the molding compound 608, and is exposed to an external environment from the molding compound 608. Specifically, the functional die 304 and the heat dissipation component (e.g., dummy silicon die) 306 are encapsulated by the molding compound 608; and a top surface 601 of the thermally conductive material 602 is not covered by the molding compound 608. Since the thermally conductive material 602 is exposed to the external environment from the molding compound 608, the FC based semiconductor package structure 600 has better heat dissipation performance than the FC based semiconductor package structure 500.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor package structure comprising:
a functional die;
a heat dissipation component;
an adhesive, wherein a bottom surface of the heat dissipation component is bonded to a top surface of the functional die via the adhesive;
a molding compound, wherein the functional die and the heat dissipation component are encapsulated by the molding compound; and
a thermally conductive material, having a physical contact with a top surface of the heat dissipation component, wherein thermal conductivity of the heat dissipation component is higher than thermal conductivity of the modeling compound, and thermal conductivity of the thermally conductive material is higher than the thermal conductivity of the heat dissipation component.

2. The semiconductor package structure of claim 1, wherein the heat dissipation component is a dummy silicon die.

3. The semiconductor package structure of claim 1, wherein the heat dissipation component is electrically non-conductive.

4. The semiconductor package structure of claim 1, wherein the thermally conductive material is encapsulated by the molding compound, without being exposed to an external environment.

5. The semiconductor package structure of claim 1, wherein the thermally conductive material is partially encapsulated by the molding compound, and is exposed to an external environment.

6. The semiconductor package structure of claim 1, wherein the thermal conductivity of the thermally conductive material is higher than thermal conductivity of silicon (Si).

7. The semiconductor package structure of claim 6, wherein the thermally conductive material is silver (Ag), copper (Cu), gold (Au), or aluminum (Al).

8. The semiconductor package structure of claim 1, wherein the semiconductor package structure is a wire bond (WB) based semiconductor package structure.

9. The semiconductor package structure of claim 1, wherein the semiconductor package structure is a flip chip (FC) based semiconductor package structure.

10. A semiconductor package structure comprising:
a functional die;
a heat dissipation component; and
an adhesive, wherein a bottom surface of the heat dissipation component is bonded to a top surface of the functional die via the adhesive;
wherein the semiconductor package structure is a flip chip (FC) based semiconductor package structure, a size of the heat dissipation component is larger than a size of the functional die, and the heat dissipation component completely covers the functional die.

11. The semiconductor package structure of claim 10, further comprising:
a molding compound, wherein the functional die is encapsulated by the molding compound; and the heat dissipation component is encapsulated by the molding compound, without being exposed to an external environment.

12. The semiconductor package structure of claim 10, further comprising:
a molding compound, wherein the functional die is encapsulated by the molding compound; and the heat dissipation component is partially encapsulated by the molding compound, and is exposed to an external environment.

13. The semiconductor package structure of claim 10, wherein the heat dissipation component is a dummy silicon die.

14. The semiconductor package structure of claim 10, further comprising:
a molding compound, wherein the functional die and the heat dissipation component are encapsulated by the molding compound; and
a thermally conductive material, having a physical contact with a top surface of the heat dissipation component, wherein thermal conductivity of the heat dissipation component is higher than thermal conductivity of the modeling compound, and thermal conductivity of the thermally conductive material is higher than the thermal conductivity of the heat dissipation component.

15. The semiconductor package structure of claim 14, wherein the heat dissipation component is a dummy silicon die.

16. The semiconductor package structure of claim 14, wherein the heat dissipation component is electrically non-conductive.

17. The semiconductor package structure of claim 14, wherein the thermally conductive material is encapsulated by the molding compound, without being exposed to an external environment.

18. The semiconductor package structure of claim 14, wherein the thermally conductive material is partially encapsulated by the molding compound, and is exposed to an external environment.

19. The semiconductor package structure of claim 14, wherein the thermal conductivity of the thermally conductive material is higher than thermal conductivity of silicon (Si).

20. The semiconductor package structure of claim 19, wherein the thermally conductive material is silver (Ag), copper (Cu), gold (Au), or aluminum (Al).
